(19) United States
(12) Patent Application Publication
(10) Pub. No.: US 2024/0355945 A1
(43) Pub. Date: Oct. 24, 2024

(54) PHOTOVOLTAIC MODULE

(71) Applicant: TAMWORTH TECHNOLOGIES LIMITED, Dublin (IE)

(72) Inventors: Donal O'FLYNN, Dublin (IE); Josef Joachim GMEINER, Dublin (IE); Michael QUINN, Dublin (IE)

(21) Appl. No.: 18/713,354

(22) PCT Filed: Nov. 24, 2022
(86) PCT No.: PCT/EP2022/083124

§ 371 Date: May 24, 2024

(30) Foreign Application Priority Data
Nov. 25, 2021 (GB) 2117057.6
Oct. 7, 2022 (GB) 2214795.3

(51) Int. Cl. H01L 31/049; H02S 40/34

(52) U.S. Cl. CPC H01L 31/049; H02S 40/34

(57) ABSTRACT

A photovoltaic (PV) module for solar power generation. The PV module comprises at least one PV element retained in a support tray. The support tray is formed of a rigid material and may not require the use of glass to provide structure stability to the PV module. The PV module may provide improved reliability and performance and may be produced by a more economical and less environmentally damaging manufacturing process. A method of forming such a PV module, a support tray for use in a PV module and a junction box for use with the PV module are also disclosed.

### FIELD

The present invention relates to a photovoltaic module, a method of forming a photovoltaic module and to a support tray for use in a photovoltaic module. In particular the present invention relates to photovoltaic modules comprising a support tray formed of a rigid material which does not require a backing sheet and/or does not require a glass cover.

### BACKGROUND

Photovoltaic modules (PV modules) typically comprise a plurality of photovoltaic elements (PV elements, for example PV cells and otherwise known as solar cells) mounted in a frame. The photovoltaic elements are electrically connected in series and/or parallel to an electrical output of the PV module. The PV elements are configured to generate electricity when exposed to sunlight via the photovoltaic effect. Several PV modules may be electrically connected together to form a photovoltaic panel and several such panels may be electrically connected together to form a photovoltaic array to supply electricity to an electricity grid, a battery or directly to electrical equipment requiring power.

The PV elements of PV modules need to be mechanically supported and protected by the PV module and also protected from weather (particularly moisture) in order to remain functional during long term use outdoors, typically for 25-30 years. In order to achieve this, typical PV modules comprise a rigid glass cover (or superstrate) and a backing sheet which may also be formed of glass or may be formed from a polymeric material. This arrangement is often housed within an aluminium frame. The PV elements are typically bonded to the backing sheet and glass cover by encapsulant layers, such as layers of EVA (ethyl vinyl acetate) adhesive.

The bonding of the PV elements to the backing sheet and glass cover is carried out by a process of lamination wherein a layer of encapsulant is provided between the PV elements and the backing sheet and another layer of encapsulant is provided between the PV elements and the glass cover. This assembly is then subjected to a vacuum to remove air in the assembly and subjected to heating to melt the encapsulant layers and promote bonding to the PV elements, backing sheet and glass cover. This lamination can be a time-consuming step of the overall PV module manufacturing process, which limits the speed and efficiency of the process.

Installation of a PV module to form a PV panel and/or PV array involves electrically connecting each PV module to a junction box. This is normally carried out by manual soldering, clamping or screwing which can be a relatively slow step in the process of producing the PV module and therefore involves significant skilled labour costs. The junction box is typically also physically connected to the PV module, for example by using an adhesive or clamping the junction box to the PV module.

As the use of solar power continues to increase around the world in order to generate electricity from this sustainable and renewable source, there is a need for continued development and improvement of PV modules and the methods used to manufacture and install such PV modules, in order to reduce the cost and improve the reliability of PV modules. Such improvements would further facilitate growth in solar electricity generation and help to reduce the impact of power generation on man-made climate change by replacing fossil fuel-based power generation.

### SUMMARY OF THE INVENTION

Although the design of PV modules discussed above has several advantages and has been widely adopted in the manufacture of PV modules, the present inventors have noted several drawbacks in these designs. For example, the glass sheeting contributes a high proportion of the weight of such PV modules, making them relatively heavy which affects the transportation costs and requires specialist handling during installation and strong mounting fixtures. Also, this PV module design commonly suffers from failure of the backing sheet and/or delamination of the encapsulant from the backing sheet, which requires costly and difficult repairs to be carried out.

It is one aim of the present invention, amongst others, to provide a photovoltaic module, method of forming a photovoltaic module, a support tray for use in a photovoltaic module and a junction box for use with such a photovoltaic module that addresses at least one disadvantage of the prior art, whether identified here or elsewhere, or to provide an alternative to existing PV modules and methods. For instance, it may be an aim of the present invention to provide a PV module which is more reliable, lighter and more economical/sustainable in production than known PV modules.

According to aspects of the present invention, there is provided a PV module, support tray, junction box and method as set forth in the appended claims. Other features of the invention will be apparent from the dependent claims, and from the description which follows.

According to a first aspect of the present invention, there is provided a photovoltaic module comprising at least one photovoltaic element retained in a support tray, wherein the support tray is formed of a rigid material.

The support tray is a rigid substrate on which the at least one PV element and any other materials which form the PV module can be mounted and supported in use. This use of the support tray formed of a rigid material to house the PV elements of the PV module provides a rigid and reliable physical support for the PV elements which means that the relatively heavy glass cover and/or glass backing sheet is not required to give the PV module sufficient rigidity and protection. The glass used in a typical PV module may contribute around 80% of the weight of the PV module. Therefore, without glass the PV module of this first aspect may be relatively lightweight. This makes transportation of the PV module easier and less costly and also facilitates handling and installation of the PV module.

Also, the use of the support tray means that the commonly used lamination process described above is not necessary and can therefore be omitted from the manufacturing process. The lamination process is relatively energy intensive because it involves establishing a vacuum and heating for a long period of time. Therefore, due to the lamination process not being required, the PV module of this first aspect can be manufactured using significantly less energy than known PV modules, for example approximately 50% less energy.

Furthermore, the use of the support tray in the PV module of this first aspect means that a typical backing sheet is not required. This avoids the problems which have been observed with current PV modules experiencing defects and failures at the backing sheet, either from delamination from the

PV elements and the encapsulant or breakdown of the backing sheet itself. Therefore, the PV module of this first aspect may be more reliable over long term use as the “backing” of the module is provided by a rigid base of the support tray.

Suitably the PV element is not laminated to a backing sheet. Suitably the PV module of this first aspect does not comprise a backing sheet for the PV element.

Furthermore, the rigid material of the support tray may resist localised heating and/or conduct heat generated in the PV elements away from the PV elements, when constructed from a suitable heat resistant and/or heat dissipating material. Such a suitable material may be a rigid foam material, such as a carbon foam material, due to the relatively large surface area of such foam materials which can efficiently dissipate heat into the surrounding atmosphere. Current PV modules can suffer from excessive heating during high sun exposure which reduces the efficiency of the PV elements due to a narrowing of the band gap in the semiconducting material of the PV elements at higher temperatures. Such PV modules retain heat and cool slowly during periods of lower sun exposure which means that the reduction in efficiency caused by the heating recovers only slowly. Some designs of PV modules have included piping for a coolant, such as water, in order to remove the unwanted heat from the PV elements. When using a rigid foam material for the support tray, this problem of unwanted and efficiency-reducing heating can be solved by the heat resistance and/or rapid cooling of the rigid foam material.

Suitably the support tray comprises a recess in which the at least one photovoltaic element is retained. The recess is suitably provided in a top face of the support tray, with respect to the orientation the support tray would be in during manufacture, with the recess facing upwards to receive the PV elements. Suitably the support tray comprises a substantially planar bottom surface.

Suitably the recess comprises a planar surface for receiving the at least one PV element. The planar surface of the recess suitably forms the base of the support tray. Suitably the support tray and the recess are substantially rectangular in plan. Suitably the recess is bounded on at least two sides by upstanding side walls of the support tray. Suitably the recess is bounded on four sides by upstanding side walls of the support tray. The upstanding side walls suitably have a constant and equal height, suitably from 0.1 mm to 100 mm.

The upstanding side walls of the support tray may form a continuous barrier surrounding the recess, such that a liquid present in the recess could not drain out of the recess when the support tray is laid flat with the upstanding walls pointing upwards (and the recess facing upwards). The recess may therefore form a vessel for receiving and retaining a liquid, such as a liquid encapsulant material, during the assembly of the PV element.

In some embodiments, at least one drainage gap is provided in the upstanding side walls to allow a liquid present in the recess to drain out of the recess. This may be useful in the assembly of the PV module using a liquid encapsulant in the base of the support tray to adhere the at least one PV element to the support tray. The drainage gap may allow any excess liquid encapsulant present to drain out of the support tray during manufacture.

The support tray suitably does not comprise any portions which cover the front of the PV element in use. For example, the upstanding side walls suitably do not comprise an overhanging region under which the PV element could be placed. Suitably the upstanding side walls are substantially vertical and substantially perpendicular with respect to the base of the support tray.

In some embodiments, the support tray is provided as a single continuous component, i.e. is not formed by attaching several components of rigid foam material together. This may provide advantages in manufacturing efficiency as the support tray may be formed in a single moulding process.

In some embodiments, the support tray may be formed from at least two support tray parts. The at least two support tray parts are suitably separately formed, for example by a moulding process, and joined together to form the support tray. The at least two support tray parts may be joined using a mechanical attachment, such as a rebar affixed to or through each support tray part, and/or using adhesive. For example, the support tray may be formed by joining two support tray parts together which each provide approximately half of the support tray. Suitably the support tray has a join which passes through the centre of the support tray, across the width of the support tray. Suitably the at least two support tray parts comprise upstanding side walls on three of four edges of the parts and no upstanding side wall on the edge which forms the join with the other part, in order to provide the recess as described above. The support tray being formed from at least two support tray parts in this manner may provide advantages in the manufacture of relatively large PV modules, for example 600 W PV modules having an approximate length and width of 2.17 m by 1.3 m. It may be difficult to form as one continuous component, for example by moulding, a support tray of a suitable size to form such a PV module. Therefore it may be more efficient to form such support trays from at least two support tray parts as described above.

The PV module of this first aspect suitably comprises an encapsulant layer arranged between the support tray and a bottom surface of the at least one photovoltaic element. The encapsulant layer may be termed an adhesive layer and functions to bind the at least one solar element to the base of the support tray. The encapsulant layer may be provided by any suitable encapsulant/adhesive material. Such suitable encapsulant materials are known in the art, such as polymeric encapsulant/adhesive materials, for example EVA. Suitably the encapsulant layer is provided by a thermoplastic adhesive material, which suitably allows the encapsulant layer to be re-liquified at high temperature in order to separate the support tray and the at least one PV element for repair or recycling. Suitably the encapsulant material is chosen to provide a stable adhesion of the at least one PV element to the support tray over a long period of time and which resists breakdown by the action of sunlight, heat and moisture.

The encapsulant layer may be present as a layer covering substantially the entire base of the recess of the support tray. The PV element may be at least partially embedded in the encapsulant layer.

Alternatively, the encapsulant may only be provided directly underneath the PV elements, between the base of the recess of the support tray and the underside of the PV elements. Therefore, the encapsulant layer may not be present on the base of the support tray between the sides of the PV elements and the upstanding side walls of the support tray.

In a further alternative, the encapsulant layer may also cover the upper side of the PV elements, therefore completely encapsulating the PV elements in the encapsulant layer. This may provide protection to the PV elements from physical damage or from weather damage. When a separate cover layer is not present, this encapsulant layer may effectively provide the cover for the PV module. The PV module of this first aspect suitably comprises a cover layer. In some embodiments, the cover layer is provided by a transparent sheet material, for example a plastic or glass sheet.

Suitably, there is no material other than any encapsulant material provided between the base of the support tray and the rear face of the PV element.

In some embodiments, the cover layer is provided by a transparent polymeric material. Therefore, the cover layer may be provided by a polymeric material arranged across a top surface of the at least one photovoltaic element. The cover layer may be formed from a liquid polymeric material which is applied to the top surface of the at least one photovoltaic element arranged in the support tray, before curing to form a solid transparent cover layer. This embodiment suitably provides the advantages discussed above in relation to the absence of glass in the PV module. The material used to form the cover layer is suitably chosen to provide transparent protective cover for the at least one PV element which resists breakdown by the action of sunlight, heat and moisture over long term use. The material used to form the cover layer is suitably chosen to be relatively lightweight, suitably significantly lighter/less dense than a glass cover material used in known PV modules.

In such embodiments, the PV module of this first aspect does not comprise a glass cover. Suitably the PV module does not comprise any glass sheet material. Suitably the PV module does not comprise any glass.

In some embodiments, the cover layer is provided by a rigid transparent cover (which may be referred to as a cover sheet), suitably a rigid transparent sheet material, such as a sheet of glass or a sheet of polymeric material. Suitably the cover sheet seals the recess of the support tray and seals the at least one PV element within the recess of the support tray. Therefore, the PV module suitably comprises a cover sheet arranged between the upstanding side walls of the support tray and which seals the recess of the support tray, for example from the ingress or egress of gas or liquid.

In such embodiments, the cover sheet may be fixed to the upper surface of the upstanding side walls. Suitably the upstanding side walls of the support tray comprise a ledge on the inside face of the upstanding side walls on which the cover sheet can be placed and attached to the support tray, for example by a suitable adhesive. Suitably the ledge is formed by a stepped profile of the upstanding side walls and is preferably a continuous planar surface surrounding the recess suitable for mating with a planar cover sheet. Suitably the ledge is configured such that the cover sheet and the upper surface of the upstanding side walls provide an approximately planar upper surface of the PV module, i.e. the cover sheet is approximately flush with the upper surface of the upstanding side walls.

The ledge may be configured to suspend the cover sheet across the recess of the support tray and may therefore provide a void in the recess between the cover sheet and the PV elements/base of the support tray. The attachment of the cover sheet to the ledge of the support tray suitably seals this void from the ingress or egress of gas or liquid. This suitably allows an atmosphere of inert gas or a vacuum to be provided in the void.

The support tray may comprise a suitable duct, port or valve to allow the void to be evacuated and/or flushed with an inert gas. Providing the void with an inert gas may protect the PV elements from degradation by moisture which may otherwise condense from the atmosphere of the void or by penetrating into the void from outside. The support tray is suitably formed from a material which is impermeable to gas and liquid and which can maintain a vacuum or an atmosphere of an inert gas over a relatively long period of time, for example several years or at least 10-20 years.

The photovoltaic module may comprise a plurality of photovoltaic elements retained in the support tray. Such a plurality of PV elements are suitably electrically connected together in series and/or in parallel by suitable arrangements of conductive wires or ribbons. Such arrangements are known in the art.

The PV elements may be any suitable known type of PV elements, for example silicon based PV elements/PV cells or perovskite based PV elements.

The at least one PV element may be arranged in the support tray against the upstanding side walls. Therefore, the support tray may be configured to provide a sung fit of the at least one PV element or plurality of PV elements in the recess of the support tray. Alternatively, the support tray may be configured to accommodate the at least one PV element or plurality of PV elements in the recess with a space between the edges of the PV elements and the upstanding side walls of the support tray. The space between the edges of the PV elements and the upstanding side walls may provide additional protection of the PV elements from damage at their side edges, especially if the encapsulant layer is provided here and the PV element is at least partially embedded in the encapsulant layer.

The PV module of this first aspect may be a mono-facial PV module comprising the structure discussed above on an upper side of the PV module and a planar bottom surface.

In some embodiments, the PV module of this first aspect is a bi-facial PV module comprising the structure discussed above, i.e. a recess and upstanding side walls, on both an upper side and lower side of the PV module. In such embodiments, the PV module is a bi-facial PV module wherein the at least one PV element retained in the support tray is exposed to light received on an upper surface of the PV module and at least one PV element retained in the support tray is exposed to light received on a lower surface of the PV module. The at least one PV element exposed to light received on a lower surface of the PV module may be the same as the at least one PV element exposed to light received on an upper surface of the PV module, for example when the base of the support tray is transparent and therefore allows light to pass to the PV element from either the upper or lower surface of the PV module. Alternatively, these PV elements may be different PV elements arranged on the opposite sides of the base of the support tray.

Such bi-facial PV modules may have improved efficiency in some situations of use due to the PV module also receiving and utilising solar radiation reflected back off a surface on which the PV module is located. In such embodiments, the PV elements may be provided on both an upper and lower surface of the base of the support tray. Alternatively, the base of the support tray may be transparent and the at least one PV element may be provided on one of the upper and lower surfaces of the base, for example wherein the at least one PV element is a perovskite PV element. Therefore the support tray of the PV module may have a base formed of a transparent material and sides (including the upstanding side walls) formed of a different, suitably non-transparent material, for example a rigid foam material as discussed in further detail below.

The support tray suitably has a size approximate to known PV modules. For example, the support tray may be rectangular in plan with a length of from 1 m to 6 m and a width of from 0.5 m to 4 m. The support tray may have a thickness of from 5 mm to 300 mm. The support tray may therefore have an approximately cuboid three-dimensional shape. The support tray may therefore have 90° edges and corners. In some embodiments, the edges and/or corners of the support tray are rounded and therefore may not be a true cuboid shape. Such rounded corners may discourage a user from clamping the PV module during installation, which may place stress on the PV module and lead to mechanical failure. Suitably the PV module is configured to be mounted onto a structure by passing suitable fixings through the support tray. The support tray may therefore be provided with appropriate mounting holes for passing said fixings through when installing the PV module.

The support tray is formed from a rigid material, for example a polymeric material, wood or a rigid foam material. The support tray suitably has a tensile and/or compressive strength suitable to resist the physical impacts and stresses common in the manufacture, installation and use of PV modules. In some embodiments, the support tray is formed of a rigid foam material. Suitable rigid foam materials include but are not limited to rigid polymeric foam materials, carbon foam materials, ceramic foam materials and glass foam materials.

In some embodiments, the rigid foam material suitably comprises lignin. Lignin is a complex organic polymer present in the cell walls of pith, roots, fruit, buds and bark and, along with hemicellulose and cellulose, is one of the most abundant components of lignocellulosic biomass. Lignin is considered a by-product in the paper and pulp industry and currently only around 2% of total lignin production utilised successfully. Therefore lignin could provide a sustainable source of polymeric material for use in the formation of the support trays for PV modules described herein.

It is believed that any type of lignin can be utilised in the rigid foam material, for example lignin obtained from softwood, hardwood or grass/annual plants. Suitable lignin can be obtained from these sources using various known processes, for example the Kraft, organosolve or soda processes. The lignin may be obtained from ionic liquid separation. In some embodiments, more than one type and/or source of lignin is used to provide the lignin of the rigid foam material.

Suitably the is present in an amount of at least 20 wt % of the rigid foam material, suitably at least 30 wt %, at least 50 wt % or at least 60 wt % of the rigid foam material.

Suitably the lignin is present in an amount of up to 95 wt % of the rigid foam material, suitably up to 90 wt %, up to 80 wt % or up to 70 wt % of the rigid foam material.

Suitably the lignin is present in an amount of from 30 wt % to 95 wt %, suitably from 40 to 90 wt %, from 40 to 80 wt % or from 50 to 80 wt % of the rigid foam material.

The inventors have recognised that in order to improve the processability of lignin in the production rigid foam material, the thermoplastic behaviour of lignin-derived materials may need to be increased and the high brittleness of the lignin-derived materials may need to be reduced. Combining the lignin with a thermoplastic polymer has been found to advantageously modify the mechanical properties of the lignin to increase the normally low tenacity and flexibility of the lignin sufficiently to allow the formation of rigid foam materials useful in the present invention.

Suitably the thermoplastic polymer is present in an amount of at least 5 wt % of the rigid foam material, suitably at least 10 wt %, at least 20 wt % or at least 30 wt % of the rigid foam material.

Suitably the thermoplastic polymer is present in an amount of up to 70 wt % of the rigid foam material, suitably up to 60 wt %, up to 50 wt % or up to 40 wt % of the rigid foam material.

Suitably the thermoplastic polymer is present in an amount of from 5 wt % to 70 wt %, suitably from to 60 wt %, from 20 to 60 wt % or from 20 to 50 wt % of the rigid foam material.

Suitably the rigid foam material comprises from 40 to 90 wt % lignin and from 10 to 60 wt % thermoplastic polymer.

The thermoplastic polymer was be selected from any one or more of: polyethylene terephthalate (PET), polyolefin elastomer (PEO), acrylonitrile-butadiene-styrene (ABS), polylactic acid (PLA), polybenzimidazole (PBI), polycarbonate (PC), polystyrene (PS), polyoxymethylene (POM) and polyester imide (PEI).

Suitably the lignin and the thermoplastic polymer are thoroughly mixed in the rigid foam material. The lignin and the thermoplastic polymer are suitably present in a polymer blend, having the relative amounts of lignin and thermoplastic polymer discussed above. The lignin and the thermoplastic polymer may be formed into a blend before forming the rigid foam material.

The thermoplastic polymer may suitably be a biodegradable and/or a bio-based material. By bio-based we mean that the material is substantially an organic material obtained from biomass, suitably from sustainably produced biomass. The rigid foam material (and therefore the support tray) may be formed substantially from bio-based materials-the lignin and an optional bio-based thermoplastic polymer.

Suitably the rigid foam material comprises at least 50% biodegradable and/or bio-based material, suitably at least 70% or at least 80% biodegradable and/or bio-based material. The rigid foam material may be substantially formed of biodegradable and/or bio-based material. Therefore the support tray suitably comprises at least 50% biodegradable and/or bio-based material, suitably at least 70% or at least 80% biodegradable and/or bio-based material. The support tray may be substantially formed of biodegradable and/or bio-based material.

The rigid foam material may be formed into the support tray using hot extrusion or pressing into a mould (or casting).

Suitably the rigid foam material has a density of less than 1.5 gcm³, suitably less than 1 gcm-³, suitably less than 0.75 gcm⁻³ or less than 0.5 gcm⁻³. Suitably the rigid foam material has a density of from 0.05 to 1 gcm⁻³, suitably from 0.1 to 0.75 gcm⁻³ or from 0.2 to 0.5 gcm⁻³. Suitable rigid foam materials have a porous structure, suitably having an open or a closed cell porous structure. Suitably the rigid foam material has a porosity of at least 30%, at least 50%, at least 70% or at least 90% of the volume of the material. Suitably the foam material is impermeable to gas and liquid. In preferred embodiments, the foam material has a density of less than 0.75 gcm⁻³, a porosity of at least 50% and is impermeable to gas and liquid.

In some embodiments, the rigid foam material may be non-carbonized. Therefore the rigid foam material, suitably comprising lignin, may be used directly to form the support tray of the PV module, without a carbonization step.

In some embodiments, the support tray is suitably formed of a carbon foam material. Therefore the rigid foam material may be a carbon foam material. Suitably the carbon foam material has a density in one or more of the ranges described above, for example a density of from 0.1 to 0.75 gcm⁻³.

Such carbon foam materials are suitably lightweight, strong and heat resistant. These properties make such carbon foams advantageous for use in forming the support tray of the PV module of the present invention. The high strength allows the material to support and protect the fragile PV elements within the module whilst being more resistant to breakage than glass and the low weight is advantageous compared to known PV modules comprising a high proportion of glass in reducing the energy required and costs involved in transporting the PV modules, and also in facilitating installation of the PV modules. Such carbon foam materials are also heat resistant and effective at dissipating heat away from a heat source due to their heat conductive properties and high surface area. This property allows the support tray formed of the carbon foam material to prevent the unwanted increase in temperature of the PV elements and accompanying decrease in electricity generation efficiency discussed above.

Such carbon foam materials may also be fire retardant and/or self-extinguishing. Therefore, constructing the support tray from such carbon foam material may significantly reduce the risk of the PV module catching fire, which can occur with known PV modules, for example after an electrical fault.

The carbon foam material is suitably formed into the desired shape of the support tray. Suitably a carbon foam precursor is formed into the shape of the support tray and then carbonised at high temperature to produce the carbon foam support tray. The carbon foam precursor may be any suitable material known to form carbon foams having the desired properties discussed above. In some embodiments, the carbon foam material is formed from lignin. Therefore, the support tray is suitably formed from a carbon foam precursor material comprising lignin. Forming the carbon foam material from a sustainable, renewable source of lignin may further reduce the environmental impact of the manufacture of the PV modules of the present invention.

The carbon foam material may be formed from a rigid foam material comprising lignin as described above, which may comprise a thermoplastic polymer, as also described above.

These advantages may apply equally, at least to some extent, to embodiments wherein the rigid foam material is not carbonized, particularly wherein the rigid foam material comprises lignin and optionally a thermoplastic polymer, as discussed above.

The photovoltaic module of this first aspect may comprise connectors for electrically connecting the PV elements in the PV module to a junction box as part of a PV panel of PV array. Suitably the connectors are male or female electrical connectors. Suitably the PV module comprises sockets electrically connected to the at least one PV element in the PV module. Suitably the connectors are arranged in the support tray, suitably the connectors are integral to the support tray, i.e. in the rigid foam material of the support tray. Suitably the support tray comprises sockets electrically connected to the at least one PV element. Suitably the sockets are configured to receive pins of a junction box to electrically connect said junction box to the PV module and therefore to the at least one PV element of the PV module.

Suitably the support tray is provided with or formed with holes into which the sockets can be inserted. Suitably the sockets are retained in the holes. Suitably the holes and the sockets are arranged in the base of the support tray. The holes are suitably through-holes in the base of the support tray, passing from a bottom surface of the support tray to the top face of the support tray, on which the at least PV element is arranged. The through-holes are configured to allow an electrical connection to pass from the socket arranged in the through-hole to the at least one PV element arranged on the support tray. Suitably the sockets are arranged such that they are accessible from the bottom surface of the support tray, i.e. from underneath the support tray when the PV module is orientated with the at least one PV element facing upwards. Suitably the openings of the sockets are proximal to or at the bottom surface of the support tray, suitably in the plane of the bottom surface of the support tray.

The connectors of the PV module discussed above are suitably configured to engage with suitable connectors on a junction box intended for use with the PV module of this first aspect. Suitably the connectors of the PV module are male or female connectors and the connectors of the junction box are corresponding female or male connectors. When the connectors of the PV module are sockets, for example located in the base of the support tray, the connectors on the junction box are pins which suitably protrude from the junction box, from a side of the junction box intended to rest against the PV module in use. Suitably the engagement of the connectors on the PV module with the connectors of the junction box securely attach the junction box to the PV module. Therefore, additional fixing, soldering, clamping and/or screwing of the junction box to the PV module is suitably not required. The junction box may otherwise comprise the features common to known junction boxes for use with PV modules, for example a pair of cables for connection of the junction box to other PV modules, diodes or other equipment in a PV panel or PV array.

In some embodiments, the connectors of the PV module are male connectors, suitably pins for engaging with sockets in the junction box. In such embodiments, the female connectors may be embedded within the junction box. The connectors being female connectors such as sockets embedded in the junction box may allow the junction box to have a thinner profile in relation to the surface of the PV module. This may be advantageous in minimising the volume of the PV module (with the junction box attached) when packaged and therefore maximising the number of packaged PV modules which can be stacked together for transportation over long distances in a fixed volume container, thereby reducing the transportation costs per PV module.

The PV module of this first aspect is suitably provided with the junction box as described above. Therefore, the PV module of this first aspect may comprise the junction box.

The photovoltaic module may comprise at least one cable duct for routing an electrical cable to and/or from the photovoltaic module. Suitably the support tray comprises the at least one cable duct for routing an electrical cable to and/or from the photovoltaic module. The cable duct is suitably arranged to engage with a cable connecting the junction box to other PV modules or equipment in a PV panel or a PV array, when such a junction box is attached to the PV module. The cable duct suitably receives and retains the cable such that the cable does not hang freely below in the PV module after installation. Such cables may be snagged by users or more commonly by livestock grazing around the PV module, which can cause damage to the cabling and/or the PV module and junction box. The cable duct therefore advantageously prevents such damage from occurring.

The photovoltaic module may comprise a battery and/or an inverter. Suitably the support tray comprises the battery and/or an inverter. The support tray may be formed with a second recess for accommodating a battery and/or a third recess for accommodating an inverter. The second and third recesses may therefore be integrally formed with the support tray. The battery and/or the inverter may be integral parts of the support tray. Suitably the battery and/or inverter are housed within the overall rectangular/cuboid shape of the support tray. Therefore, the battery and/or inverter suitably do not protrude from the top or bottom faces of the support tray. This arrangement suitably provides a compact PV module wherein the battery and/or inverter are provided with physical protection by the support tray.

According to second aspect of the present invention, there is provided a support tray for use in a photovoltaic module, wherein the support tray comprises a recess for receiving and retaining at least one photovoltaic element, and wherein the support tray comprises through-holes for receiving sockets configured for electrically connecting to said at least one photovoltaic element.

The support tray of this second aspect may have any of the suitable features and advantages described in relation to the first aspect.

According to a third aspect of the present invention, there is provided a junction box for use with PV module, the junction box comprising male or female connectors configured to engage with connectors in said PV module.

The connectors may be any suitable male or female connectors which can engage in an electrical connection with corresponding female or male connectors in said PV module. The connectors are suitably push fit connectors which do not require soldering to said PV panel.

In some embodiments, the connectors protrude from a face of the junction box, suitably male connectors, for example pins. The protruding connectors may comprise at least two pins. In some embodiments the protruding connectors comprise four pins.

In some embodiments, the connectors are embedded within the junction box and are accessible from a face of the junction box, for example female connectors such as sockets for receiving pins on said PV module. The connectors being female connectors such as sockets may advantageously allow the junction box to have a thinner profile in relation to the surface of said PV module which it is attached to, as discussed in relation to the first aspect.

According to a fourth aspect of the present invention, there is provided a method of forming a photovoltaic module, the method comprising the steps of:
a) providing a support tray formed of a rigid material;
b) applying an encapsulant to a base of the support tray;
c) arranging at least one photovoltaic element on the encapsulant; and optionally
d) forming a cover layer on an upper surface of the at least one photovoltaic element.

Suitably the steps of the method are carried out in the order step a) followed by step b) followed by step c) followed by step d).

The PV module, support tray, rigid material, encapsulant, PV element and cover layer of the method of this fourth aspect may have any of the suitable features and advantages described in relation to the first aspect.

Suitably the support tray provided in step a) is formed by forming a precursor material into the shape of the support tray and then converting the precursor material into a rigid foam material. For example, the support tray may be formed by forming a carbon foam precursor material into the shape of the support tray and then carbonising the carbon foam precursor material into the carbon foam material. Methods of producing such rigid foam material, for example carbon foam material, may be known in the art.

The support tray suitably has the size, shape and features described above in relation to the first aspect. Suitably the support tray comprises a planar bottom surface and a planar top surface, wherein the top surface is provided with a recess for receiving the at least one PV element. Suitably the recess is bounded on four sides by upstanding side walls of the support tray, as described above in relation to the first aspect. The top surface of the support tray provides the base onto which the encapsulant and the at least one PV element is placed. When the recess is present, the base can be considered to be bottom of the recess which is bounded by the upstanding side walls.

Step b) of the method involves applying an encapsulant to a base of the support tray. The encapsulant may be a liquid and may be dispensed into the base of the support tray, suitably into the recess of the support tray, by a suitable application method, such as pouring or spraying. The amount of liquid encapsulant applied to the base of the support tray may be accurately dosed to achieve a specific thickness of the encapsulant layer. The support tray may be provided with drainage gaps as described in relation to the first aspect to allow any excess liquid encapsulant to drain out of the base of the support tray during step b) or step c) of the method.

Alternatively, the encapsulant may be a solid at the temperature which the step b) is carried out at (for example room temperature) and therefore may be applied as a sheet onto the support tray, suitably into the recess of the support tray.

Step c) of the method involves arranging at least one photovoltaic element on the encapsulant. Therefore, the encapsulant is arranged between the at least one PV element and the base of the support tray. The encapsulant functions to bind the at least one PV element onto the base of the support tray. Step c) may involve allowing the encapsulant to cure in order to bind the at least one PV element onto the base of the support tray. Wherein the encapsulant is applied in step b) as a solid, such as a sheet, step c) suitably involves heating and melting the encapsulant and then subsequently allowing the liquified encapsulant to cure to bind the at least one PV element to the support tray.

The at least one PV element comprises an upper surface which is intended to be orientated upwards towards the sun in use. The PV element is therefore arranged on the support tray with the upper surface facing upwards, away from the base of the support tray.

Step d) of the method, when present, involves forming a cover layer on an upper surface of the at least one photovoltaic element. The cover material may be as described in relation to the first aspect. The cover layer may be provided by a rigid sheet of glass or polymeric material laid onto the at least one PV element and secured to the PV module. Such a cover layer may be secured to the PV module using an adhesive or encapsulant material as described above. Preferably, the PV module does not comprise glass so the cover layer is preferably provided by a polymeric material. In some embodiments, the cover layer is provided by applying a liquid polymeric cover material to the upper surface of the least one PV element, and to any surrounding parts of the base of the support tray which are not covered by the at least one PV element, and allowing the liquid polymeric cover material to cure to form a solid, transparent cover layer.

Suitably the method of this fourth aspect does not require or comprise a step of vacuum lamination commonly used in the manufacture of known PV modules. Suitably the method does not comprise a step of laminating an encapsulant to a backing sheet, for example a backing sheet of glass or polymeric material.

The method of this fourth aspect may be adapted to provide the bi-facial PV module embodiment described in relation to the first aspect by repeating the steps b) to d) where appropriate on the opposite side of a suitable support tray configured for producing such a bi-facial PV module.

### BRIEF DESCRIPTION OF THE DRAWINGS

For a better understanding of the invention, and to show how example embodiments may be carried into effect, reference will now be made to the accompanying drawings in which:

FIG. 1 is a perspective view of a PV module 100 according to the first aspect of the present invention.

FIG. 2 is a perspective view of a PV module 100 according to the first aspect of the present invention from underneath.

FIG. 3 is a perspective view of a support tray 200 for a PV module according to the second aspect of the invention.

FIG. 4 is a cross section view of the PV module 100 along line A of FIG. 1.

FIG. 5 is a perspective view of a junction box 300 according to the third aspect of the invention, for use with the PV module of FIG. 1.

FIG. 6 is a plan view from above of a PV module 400 according to a further embodiment of the first aspect of the invention.

FIG. 7 is an exploded view of the PV module 400 shown in FIG. 6.

FIG. 8 is a perspective view of a PV module 600 according to a further embodiment of the first aspect of the invention.

FIG. 9 is a cross section view of the PV module 600 shown in FIG. 8, along line B.

### DETAILED DESCRIPTION OF THE EXAMPLE EMBODIMENTS

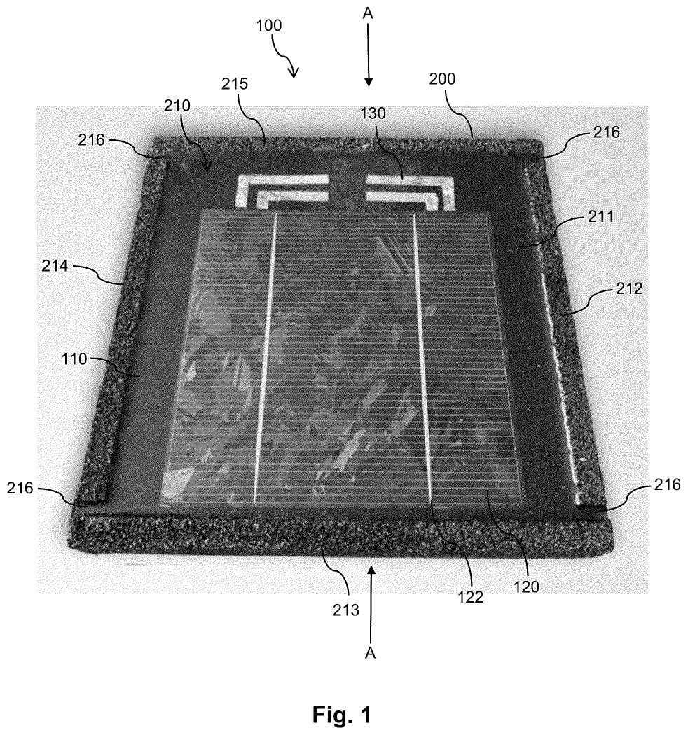

FIG. 1 shows a PV module 100 comprising a support tray 200 and a plurality of PV elements 120. The support tray 200 comprises a recess 210 which is defined by a base 211 and upstanding side walls 212-215. The base 211 provides the majority of the upper surface of the support tray 200. The upstanding side walls 212-215 extend 3.5 mm above the base 201. Between each adjacent pair of upstanding side walls 212-215 is provided a drainage gap 216 which co-extends with the base 211, in the same plane as the base 211. The support tray 200 is formed of the rigid carbon foam material CFoam 20 manufactured by CFoam LLC, USA. The support tray has a length of 180 mm, a width of 180 mm and a thickness of 24 mm.

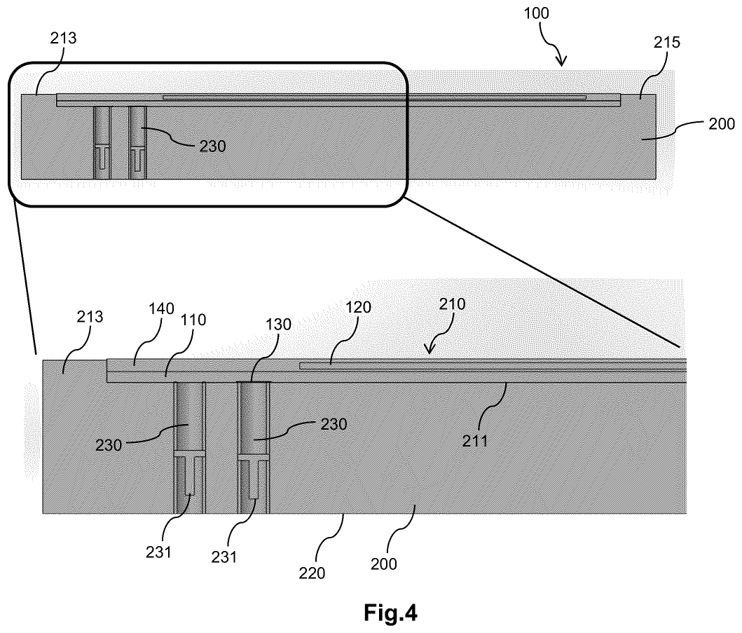

PV elements 120 are arranged in the recess 210 of the support tray 200 with the upper surfaces of the PV elements facing upwards, away from the base 211. The PV elements are bonded to the base 211 of the support tray 200 by encapsulant layer 110 which is a layer of a standard epoxy resin formed from a two-part system (A +B). The encapsulant layer 110 is arranged between the PV elements 120 and the base 211 of the support tray 200 and also in the margin area between the PV elements 120 and the upstanding side walls 212-215. Electrical contacts 130 are provided on the base 211 of the support tray 200 and are electrically connected to the PV elements 120. The electrical contacts 130 are covered by the encapsulant layer 110. Therefore in constructing the PV module 100, the electrical contacts 130 are applied to the support tray 200 before the encapsulant layer 110. This arrangement is shown in the cross section along line A of FIG. 4. The PV elements are electrically connected to each other by conductive ribbons 122, as in known PV modules.

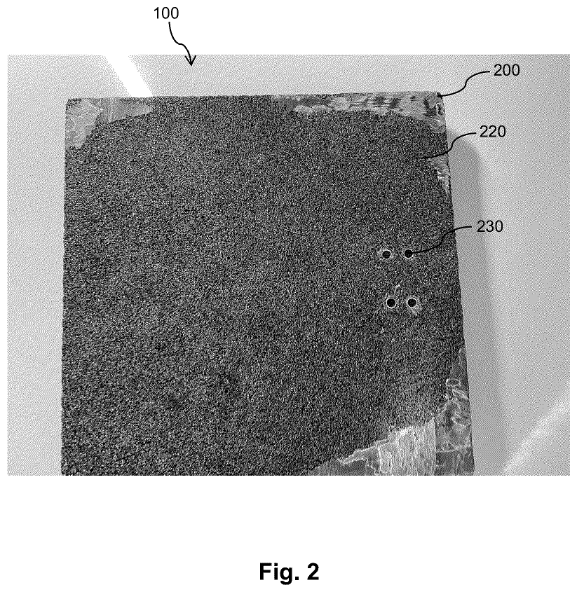

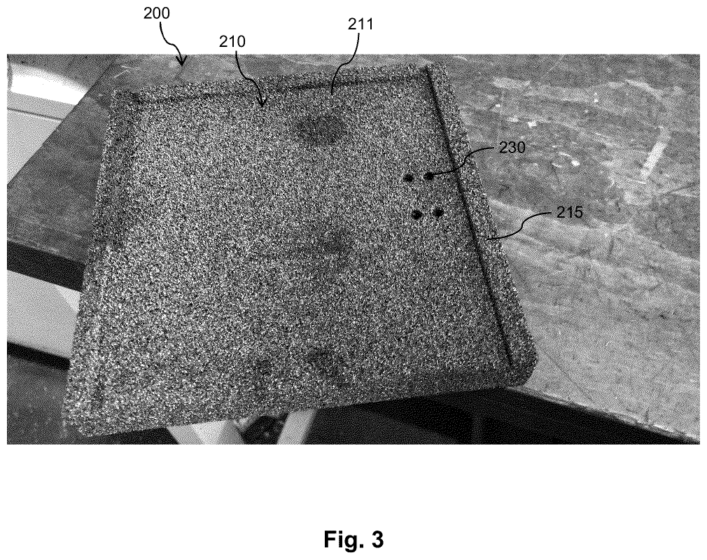

FIG. 2 shows the underneath of the PV module 100 which comprises the bottom surface 220 of the support tray 200. In the bottom surface 220, four through-holes 230 are provided which pass from the opening shown in the bottom surface 220 to an opening in the base 211 of the support tray (shown in FIG. 3). Each through-hole accommodates a socket 231 (see FIG. 4), the opening of which is located adjacent to the opening of the through-holes 230 in the bottom surface 220.

FIG. 3 shows the support tray 200 without the PV elements 120 and encapsulant layer 110. This view shows the openings of the through-holes 230 in the base 211 of the support tray.

Some aspects of the structure of the PV module described above are shown more clearly by the cross-section view of FIG. 4. FIG. 4 shows the recess 210 of the support tray 200 bounded by the upstanding side walls 213 and 215 and base 211. The encapsulant layer 110 is arranged on and across the base 211 between the upstanding side walls 213 and 215, and is adhered to the base 211. The PV elements 120 are arranged on top of and adhered to the encapsulant layer 110. FIG. 4 also shows an optional cover layer 140 of transparent polymeric material which has been added to and across the upper surfaces of the PV elements and to the encapsulant layer in the margin region between the edges of the PV elements 120 and the upstanding side walls 213 and 215 of the support tray. The cover layer provides a protective coating for the PV module, in particular for the PV elements, which resists damage from sunlight, heat, debris and rain during the operational lifetime of the PV module.

FIG. 4 also shows two of the through-holes 230 passing through the support tray 200 from the base 211 to the bottom surface 220. The through-holes 230 comprise sockets 231 which are configured to receive corresponding pins of a junction box intended to be connected to the PV module 100 in use. The open ends of the sockets are arranged at the opening of the through-holes 230 in the bottom surface 220 of the support tray. At the opening of the through-holes 230 at the base 211, the electrical contacts 130 overlay the openings and are electrically connected to the sockets 231 in the through-holes 230. Therefore, the PV elements 120, which are electrically connected to the electrical contacts 130 (connection not shown), are electrically connected to the sockets 231 in the through-holes 230 of the support tray 200. The through-holes 230 provide a secure and protected location for such electrical connections.

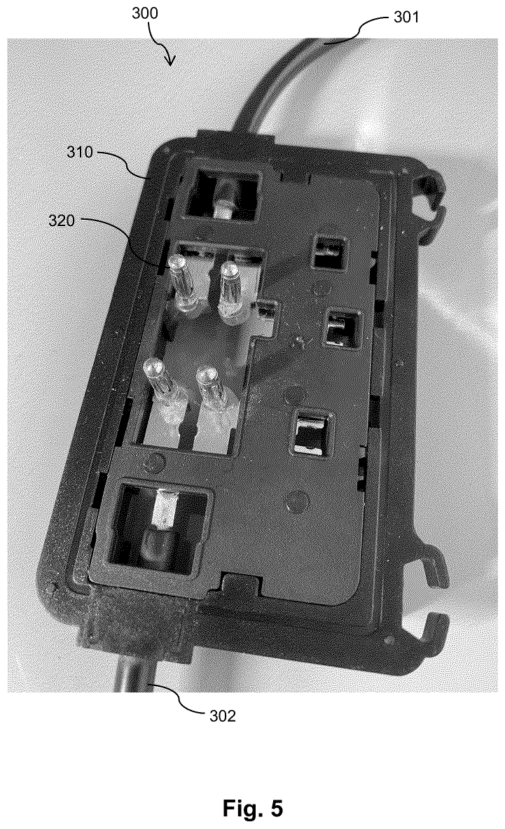

FIG. 5 shows a junction box 300 for use with the PV module 100. The junction box comprises cables 301 and 302, housing 310 and four pins 320. The pins 320 are configured to engage with the four sockets 231 arranged in the PV module 100 to provide an electrical connection between the PV module 100 and the junction box 300. The cables comprise appropriate connectors to electrically connect the junction box 300 to an output. The housing 310 comprises appropriate electrical circuitry and hardware which connects the pins 320 to the cables 301 and 302 in order to transfer electricity generated in the PV module, through the pins 320 and cables 301 and 302 to an appropriate output connected to the cables. The junction box 300 is fitted to the PV module 100 by simply inserting the pins 320 into the sockets 230 which then securely retains the junction box 300 against the bottom surface 220 of the PV module 100 and provides a secure electrical connection between the junction box 300 and the PV module.

The PV module 100 and junction box 300 described above may provide significant advantages over current designs of PV modules. For example, the PV module 100 comprising the support tray 200 formed of a rigid foam material such as carbon foam may be less liable to the breakdown during long term use than current PV modules, may be more economical and less environmentally damaging to produce and may be easier to install and maintain.

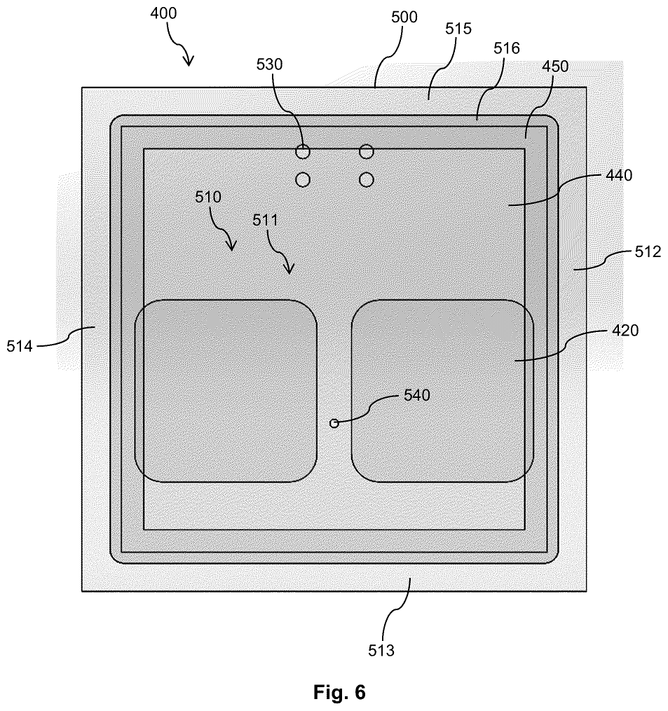

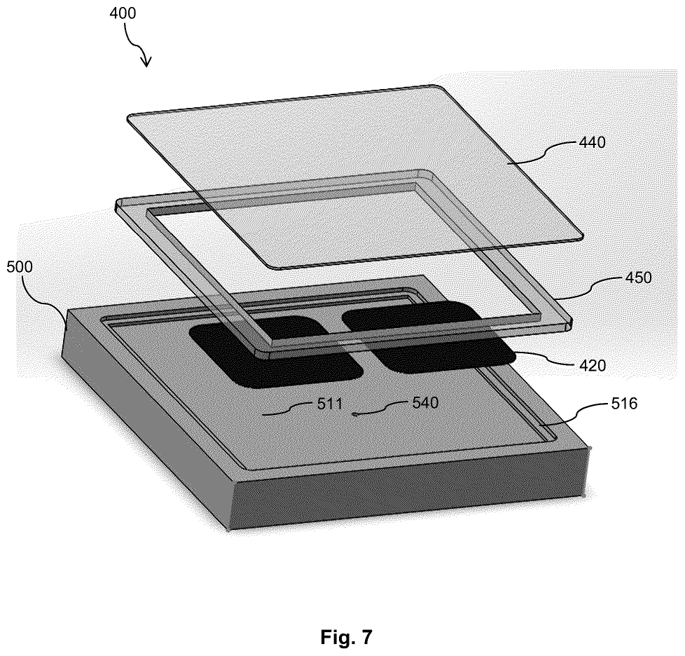

FIG. 6 shows PV module 400 which is an alternative embodiment of the PV module of the first aspect of the present invention. PV module 400 comprises support tray 500, PV elements 420 and cover sheet 440. The support tray 500 differs from support tray 200 described above in that a ledge 516 is provided in the upstanding side walls 512-515 around the recess 510. This ledge 516 is present to support the cover sheet 440 of the PV module 400. The ledge 516 can be seen more clearly in the exploded view of FIG. 7. The ledge 516 is provided with a cover adhesive material 450 of thermoplastic polymer which forms a continuous ring around the ledge 516 and therefore around the recess 510. The cover sheet 440 is laid on top of the cover adhesive material 450 to seal the recess 510 and form a barrier to gas or liquid entering or leaving the recess 510. The cover sheet 440 is rigid and transparent and may be formed of glass or a suitable polymeric material. In this embodiment, the recess 510 comprises a void between the rigid cover 440 and the base 511 of the support tray 500 on which the PV elements 420 are arranged. This void may be filled with an inert gas or provided with a vacuum. The PV module 400 comprises duct 540 for evacuating and sealing the void, if a vacuum is to be provided in the void, or for flushing with an inert gas, if an inert gas atmosphere is to be provided in the void.

The PV module 400 may be particularly suitable for use with PV elements 420 which are perovskite-based PV elements. Such perovskite PV elements are more prone to degradation than silicon-based PV elements and therefore may benefit from being encased in the recess 510 by the rigid cover 440 and provided with a vacuum or an inert atmosphere in the void between the cover 440 and the base 511 of the support tray 500, in order to slow down degradation of the PV elements. PV module 400 also facilitates removal of such PV elements 420 for regeneration or replacement by liquification of the cover adhesive material 450, for example a thermoplastic polymer, and removal of the rigid cover 440 which provides access to the PV elements 420. Suitably PV module 400 does not comprise a coating on the PV elements 420, such as a coating of an encapsulant, which would hinder the removal and replacement of the PV elements 420.

The PV module 400 suitably comprises the arrangement of electrical contacts and connectors (not shown) for engaging with a junction box 300 described in relation to PV module 100. The support tray 500 of PV module 400 is suitably formed from the same carbon foam material as support tray 200 of PV module 100 and is impermeable to gas or liquid and therefore able to retain an inert gas atmosphere or maintain a vacuum in the void during long term usage of the PV module 400.

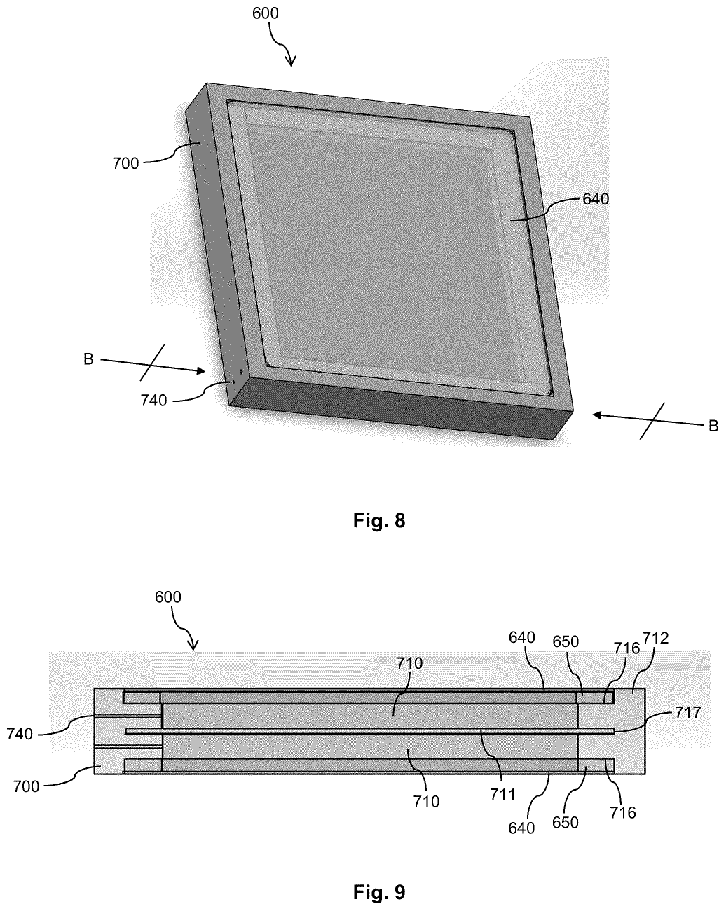

FIGS. 8 and 9 shows PV module 600 which is a further alternative embodiment of the PV module of the first aspect of the present invention. PV module 600 comprises support tray 700 and rigid cover sheet 640. The support tray 700 is similar to support tray 500 of PV module 400 shown in FIGS. 6 and 7 in that a ledge 716 is provided in upstanding side walls 712-715 around the recess 710, for accommodating rigid cover sheet 640 which is bound to the ledge 716 of the support tray 700 by a cover adhesive material 650, as described above in relation to PV module 400. The support tray 700 differs from support tray 500 described above in that both the upper and lower faces of the support tray 700 are provided with a recess 710, upstanding side walls 712-715 and a ledge 716, and in that the base 711 is formed of a transparent material, for example glass or a transparent polymeric material. The PV module 600 comprises a rigid cover 640 and cover adhesive material 650 on each of the upper and lower faces of the support tray 700 and therefore forms a bi-facial PV module 600. Suitable PV elements (not shown) are provided on one or both of the upper and lower sides of the base 711 of the support tray 700, suitably only on the upper side of the base 711. Such a PV module 600 can receive light from either the upper or lower faces of the PV module 600 which may increase the amount of electricity generated by the PV module, particularly when installed on a relatively reflective surface which reflects a significant amount of sunlight back up from the surface onto the lower face of the PV module 600.

The cross-section view of FIG. 9 shows that base 711, of glass or rigid polymeric material for example, is retained in the support tray 700 in groove 717 which is provided all around the support tray 700. The support tray 700 may be formed from the same carbon foam material described above for support tray 200, i.e. a different material to the transparent base 711. The support tray 700 may be formed around the transparent base 711, making base 711 integral to the support tray.

The support tray 700 is provided with ducts 740 which function as described above for duct 540 in support tray 500, i.e. for evacuating and sealing the voids or flushing the voids with an inert gas.

Although a few preferred embodiments have been shown and described, it will be appreciated by those skilled in the art that various changes and modifications might be made without departing from the scope of the invention, as defined in the appended claims.

Throughout this specification, the term “comprising” or “comprises” means including the component(s) specified but not to the exclusion of the presence of other components. The term “consisting essentially of” or “consists essentially of” means including the components specified but excluding other components except for materials present as impurities, unavoidable materials present as a result of processes used to provide the components, and components added for a purpose other than achieving the technical effect of the invention. Typically, when referring to compositions, a composition consisting essentially of a set of components will comprise less than 5% by weight, typically less than 3% by weight, more typically less than 1% by weight of non-specified components.

The term “consisting of” or “consists of” means including the components specified but excluding addition of other components.

Whenever appropriate, depending upon the context, the use of the term “comprises” or “comprising” may also be taken to encompass or include the meaning “consists essentially of” or “consisting essentially of”, and may also be taken to include the meaning “consists of” or “consisting of”.

The optional features set out herein may be used either individually or in combination with each other where appropriate and particularly in the combinations as set out in the accompanying claims. The optional features for each aspect or exemplary embodiment of the invention as set out herein are also to be read as applicable to any other aspect or exemplary embodiments of the invention, where appropriate. In other words, the skilled person reading this specification should consider the optional features for each exemplary embodiment of the invention as interchangeable and combinable between different exemplary embodiments.

Attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, and drawings), and/or all of the steps of any method or process so disclosed, may be combined in any combination, except combinations where at least some of such features and/or steps are mutually exclusive.

Each feature disclosed in this specification (including any accompanying claims, and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, and drawings), or to any novel one, or any novel combination, of the steps of any method or process so disclosed.

1. A photovoltaic module comprising at least one photovoltaic element retained in a support tray, wherein the support tray is formed of a rigid material.

2. The photovoltaic module according to claim 1, wherein the rigid material of the support tray is a rigid foam material and has a density of less than 1 gcm⁻³.

3. The photovoltaic module according to claim 1 or claim 2, wherein the rigid foam material comprises lignin.

4. The photovoltaic module according to claim 3, wherein the rigid foam material comprises a thermoplastic polymer.

5. The photovoltaic module according to any one of the preceding claims, wherein the support tray is formed of a carbon foam material.

6. The photovoltaic module according to claim 5, wherein the carbon foam material is formed from lignin.

7. The photovoltaic module according to any one of the preceding claims, wherein the support tray comprises a recess in which the at least one photovoltaic element is retained.

8. The photovoltaic module according to claim 7, wherein the support tray and the recess are substantially rectangular in plan and the recess is bounded on at least two sides by upstanding side walls of the support tray.

9. The photovoltaic module according to claim 8, wherein the recess is bounded on four sides by upstanding side walls of the support tray.

10. The photovoltaic module according to claim 9, comprising a cover sheet arranged between the upstanding side walls of the support tray and which seals the recess of the support tray.

11. The photovoltaic module according to claim 10, wherein the upstanding side walls comprise a ledge on which the cover sheet is arranged.

12. The photovoltaic module according to claim 10 or claim 11, comprising a void between the at least one PV element and the cover sheet, wherein the void comprises an inert gas or a vacuum.

13. The photovoltaic module according to any one of the preceding claims, wherein an encapsulant layer is arranged between the support tray and a bottom surface of the at least one photovoltaic element.

14. The photovoltaic module according to any one of the preceding claims, wherein a polymeric material arranged across a top surface of the at least one photovoltaic element.

15. The photovoltaic module according to any one of the preceding claims, which does not comprise a glass sheet.

16. The photovoltaic module according to any one of the preceding claims comprising a plurality of photovoltaic elements retained in the support tray.

17. The photovoltaic module according to any preceding claim which is a bi-facial photovoltaic module wherein the at least one photovoltaic element retained in the support tray is exposed to light received on an upper surface of the photovoltaic module and at least one photovoltaic element retained in the support tray is exposed to light received on a lower surface of the photovoltaic module.

18. The photovoltaic module according to claim 17, wherein the support tray comprises a transparent base.

19. The photovoltaic module according to any one of the preceding claims, wherein the support tray comprises male or female connectors electrically connected to the at least one photovoltaic element.

20. The photovoltaic module according to any one of the preceding claims, wherein the male or female connectors are configured to receive female or male connectors of a junction box to electrically connect said junction box to the photovoltaic module.

21. The photovoltaic module according to claim 20, comprising a junction box having pins for electrically connecting the junction box to the sockets in the support tray.

22. The photovoltaic module according to any one of the preceding claims, wherein the support tray comprises at least one cable duct for routing an electrical cable to and/or from the photovoltaic module.

23. The photovoltaic module according to any one of the preceding claims, wherein the support tray comprises battery and/or an inverter.

24. A method of forming a photovoltaic module, the method comprising the steps of:
a) providing a support tray formed of a rigid material;
b) applying an encapsulant to a base of the support tray;
c) arranging at least one photovoltaic element on the encapsulant; and optionally
d) forming a cover layer on an upper surface of the at least one photovoltaic element.

25. A support tray for use in a photovoltaic module, wherein the support tray comprises a recess for receiving and retaining at least one photovoltaic element, and wherein the support tray comprises through-holes for receiving sockets configured for electrically connecting to said at least one photovoltaic element.

26. A junction box for use with photovoltaic module, the junction box comprising male or female connectors configured to engage with female or male connectors in said photovoltaic module.
